(19) United States
(12) Patent Application Publication
(10) Pub. No.: US 2025/0275129 A1
(43) Pub. Date: Aug. 28, 2025

(54) MEMORY DEVICES HAVING VERTICAL TRANSISTORS IN OTP MEMORY CELLS

(71) Applicant: Yangtze Memory Technologies Co., Ltd., Wuhan (CN)

(72) Inventors: Shiqi HUANG, Wuhan (CN); Liang CHEN, Wuhan (CN); Yanhong WANG, Wuhan (CN); Wei LIU, Wuhan (CN); Zichen LIU, Wuhan (CN)

(21) Appl. No.: 18/741,745

(22) Filed: Jun. 12, 2024

(30) Foreign Application Priority Data
Feb. 26, 2024 (CN) 202410210806.7

(51) Int. Cl. H10B 20/25; H01L 23/00; H10B 12/00

(52) U.S. Cl. CPC H10B 20/25; H01L 24/08; H01L 24/80; H10B 12/315; H01L 2224/08145; H01L 2224/80895; H01L 2224/80896; H01L 2924/1436; H01L 2924/1453

(57) ABSTRACT

The present disclosure describes memory systems and devices having vertical transistors in one-time-program (OTP) memory cells and fabrication methods thereof. An example semiconductor device includes a first array of memory cells including at least a first memory cell. The first memory cell includes a first vertical transistor and a storage structure coupled to the first vertical transistor in a first direction. The first array of memory cells is in a first area of a first semiconductor structure of the semiconductor device. The semiconductor device further includes a second array of memory cells including at least a second memory cell. The second memory cell includes a second vertical transistor in a second area of the first semiconductor structure. The second area is adjacent to the first area in a second direction perpendicular to the first direction.

### CROSS-REFERENCE TO RELATED APPLICATIONS

This application claims priority to Chinese Patent Application No. 202410210806.7, filed on Feb. 26, 2024, which is hereby incorporated by reference in its entirety.

### TECHNICAL FIELD

The present disclosure relates to semiconductor devices and fabrication methods thereof.

### BACKGROUND

Semiconductor industry is driven by the need to produce smaller and faster chips. Makers of memory devices and systems also are pushing to improve scaling techniques. Dynamic random-access memory (DRAM) is a common type of memory device widely used in computer systems. The mainstream DRAM architecture has been using an 8F² cell design and a 6F² cell design for many years and is now in the process of shifting to a 4F² cell design.

### SUMMARY

The present disclosure describes memory systems and devices having vertical transistors in one-time-program (OTP) memory cells and fabrication methods thereof.

One aspect of the present disclosure features a semiconductor device. The semiconductor device includes a first array of memory cells including at least a first memory cell. The first memory cell includes a first vertical transistor and a storage structure coupled to the first vertical transistor in a first direction. The first array of memory cells is in a first area of a first semiconductor structure of the semiconductor device. The semiconductor device further includes a second array of memory cells including at least a second memory cell. The second memory cell includes a second vertical transistor in a second area of the first semiconductor structure. The second area is adjacent to the first area in a second direction perpendicular to the first direction.

In some implementations, the second memory cell is an OTP memory cell and further includes an access transistor coupled to the second vertical transistor, and the access transistor is in a second semiconductor structure of the semiconductor device.

In some implementations, the second memory cell is an OTP memory cell, the second vertical transistor is an access transistor of the OTP memory cell, the OTP memory cell further includes an anti-fuse capacitor coupled to the second vertical transistor, and the anti-fuse capacitor is in a second semiconductor structure of the semiconductor device.

In some implementations, a source of the access transistor is coupled to a source of the second vertical transistor.

In some implementations, the second array of memory cells includes a first group of vertical transistors coupled to a first program line through a gate of each vertical transistor of the first group of vertical transistors, the first group of vertical transistors includes the second vertical transistor, and the first group of vertical transistors is comprised in a first array of vertical transistors in the second area of the first semiconductor structure.

In some implementations, each vertical transistor of the first group of vertical transistors is coupled to a corresponding access transistor in the second semiconductor structure through a first terminal of the vertical transistor, and a second terminal of the vertical transistor is floating.

In some implementations, the second array of memory cells further includes a second group of vertical transistors coupled to a second program line through a gate of each vertical transistor of the second group of vertical transistors, and the second group of vertical transistors is comprised in a second array of vertical transistors in the second area of the first semiconductor structure.

In some implementations, the first group of vertical transistors is comprised in a same row or a same column of the first array of vertical transistors, and a gate of each vertical transistors of the first group of vertical transistors is part of a same connection line of the first array of vertical transistors.

In some implementations, a terminal of each vertical transistor of the first group of vertical transistors is directly connected to a contact structure extending along the first direction, and the contact structure is further connected to a conductive line including a metal and extending in a direction perpendicular to the first direction.

In some implementations, a terminal of each vertical transistor of the first group of vertical transistors is directly connected to a conductive line extending along a direction perpendicular to the first direction, and the conductive line includes a metal.

In some implementations, each vertical transistor of the first group of vertical transistors is in a different row or a different column of the first array of vertical transistors, and each vertical transistor of the first group of vertical transistors is coupled to the first program line through a respective connection line of the first array of vertical transistors.

In some implementations, a hybrid bonding structure is located between the second vertical transistor and the access transistor, the second vertical transistor and the access transistor are located at different positions along the first direction, and the second vertical transistor and the access transistor are coupled through at least one contact structure extending along the first direction and at least one conductive line extending along the second direction.

In some implementations, the first program line is coupled to the second semiconductor structure through a hybrid bonding structure, each vertical transistor of the first group of vertical transistors includes a first terminal coupled to a corresponding access transistor in the second semiconductor structure and a second terminal coupled to a floating bit line, and the second terminal of the vertical transistor is a drain of the vertical transistor.

Another aspect of the present disclosure features a semiconductor device. The semiconductor device includes an array of OTP memory cells including at least an OTP memory cell. The OTP memory cell includes a vertical transistor in a first semiconductor structure of the semiconductor device and an access transistor in a second semiconductor structure of the semiconductor device. The first semiconductor structure and the second semiconductor structure are bonded through a hybrid bonding structure. The access transistor is coupled to the vertical transistor.

In some implementations, the semiconductor device further includes an array of dynamic random-access memory (DRAM) cells including at least a DRAM cell. The DRAM cell includes a first vertical transistor and a storage structure coupled to the first vertical transistor in a first direction. The array of DRAM cells is in a first area of a first semiconductor structure of the semiconductor device. The vertical transistor of the OTP memory cell is a second vertical transistor in a second area of the first semiconductor structure, and the second area is adjacent to the first area in a second direction perpendicular to the first direction.

In some implementations, a source of the access transistor is coupled to a source of the second vertical transistor.

In some implementations, the array of OTP memory cells includes a first group of vertical transistors coupled to a first program line through a gate of each vertical transistor of the first group of vertical transistors, the first group of vertical transistors includes the second vertical transistor, and the first group of vertical transistors is comprised in a first array of vertical transistors in the second area of the first semiconductor structure.

In some implementations, each vertical transistor of the first group of vertical transistors is coupled to a corresponding access transistor in the second semiconductor structure through a first terminal of the vertical transistor, and a second terminal of the vertical transistor is floating.

In some implementations, the array of OTP memory cells further includes a second group of vertical transistors coupled to a second program line through a gate of each vertical transistor of the second group of vertical transistors, and the second group of vertical transistors is comprised in a second array of vertical transistors in the second area of the first semiconductor structure.

In some implementations, the first group of vertical transistors is comprised in a same row or a same column of the first array of vertical transistors, and a gate of each vertical transistors of the first group of vertical transistors is part of a same connection line of the first array of vertical transistors.

In some implementations, a terminal of each vertical transistor of the first group of vertical transistors is directly connected to a contact structure.

In some implementations, a terminal of each vertical transistor of the first group of vertical transistors is directly connected to a conductive line.

In some implementations, each vertical transistor of the first group of vertical transistors is in a different row or a different column of the first array of vertical transistors, and each vertical transistor of the first group of vertical transistors is coupled to the first program line through a respective connection line of the first array of vertical transistors.

In some implementations, a hybrid bonding structure is located between the second vertical transistor and the access transistor, the second vertical transistor and the access transistor are located at different positions along the first direction, and the second vertical transistor and the access transistor are coupled through at least one contact structure extending along the first direction and at least one conductive line extending along the second direction.

In some implementations, the first program line is coupled to the second semiconductor structure through a hybrid bonding structure, each vertical transistor of the first group of vertical transistors includes a first terminal coupled to a corresponding access transistor in the second semiconductor structure and a second terminal coupled to a floating bit line, and the second terminal of the vertical transistor is a drain of the vertical transistor.

Another aspect of the present disclosure features a method for forming a semiconductor device. The method includes forming a first vertical transistor in a first area of a first semiconductor structure of the semiconductor device. The first vertical transistor includes a first semiconductor body and a first gate structure in contact with at least one side of the first semiconductor body. The first vertical transistor is an anti-fuse capacitor of an OTP memory cell. The method further includes forming a transistor in a second semiconductor structure of the semiconductor device and bonding the first semiconductor structure and the second semiconductor structure through a hybrid bonding structure. The first vertical transistor is coupled to the transistor through the hybrid bonding structure.

In some implementations, the method further includes forming a second vertical transistor in a second area of the first semiconductor structure. The second vertical transistor includes a second semiconductor body and a second gate structure in contact with at least one side of the second semiconductor body. The method further includes forming a storage structure coupled to the second vertical transistor along a first direction. The second area is adjacent to the first area in a second direction perpendicular to the first direction.

In some implementations, the first vertical transistor and the second vertical transistor are formed during a same operation. The operation includes forming the first semiconductor body of the first vertical transistor in the first area of the first semiconductor structure and the second semiconductor body of the second vertical transistor in the second area of the first semiconductor structure. The first semiconductor body and the second semiconductor body are formed on a first side of the first semiconductor structure. The operation further includes forming the first gate structure of the first vertical transistor and the second gate structure of the second vertical transistor.

In some implementations, the method further includes covering the first area of the first semiconductor structure with a mask while forming the storage structure.

In some implementations, the method further includes removing a first portion of the first area the first semiconductor structure from the first side to expose a first end of the first semiconductor body and forming a first connection line and a first contact structure. The first connection line connects the first end of the first semiconductor body and the first contact structure, and the first contact structure is coupled to the hybrid bonding structure.

In some implementations, the method further includes removing a second portion of the first semiconductor structure from a second side to expose a second end of the first semiconductor body and forming a second connection line in contact with the second end of the first semiconductor body. The second connection line is floating.

In some implementations, the method further includes forming a third connection line and a second contact structure. The third connection line connects the first gate structure and the second contact structure. The second contact structure is coupled to the hybrid bonding structure.

### BRIEF DESCRIPTION OF DRAWINGS

FIG. 1 illustrates a side view of a cross-section of an example semiconductor device, according to some aspects of the present disclosure.

FIGS. 2A-2B illustrate top views of example semiconductor devices, according to some aspects of the present disclosure.

FIGS. 3A-3H illustrate example one-time-programmable (OTP) memory cell arrays, according to some aspects of the present disclosure.

FIGS. 4A-4E illustrate a fabrication process for forming an example semiconductor structure, according to some aspects of the present disclosure.

FIG. 5 illustrates a flowchart of an example method for forming a semiconductor device, according to some aspects of the present disclosure.

FIG. 6 illustrates a block diagram of a system having one or more semiconductor devices, according to some aspects of the present disclosure.

Like reference numbers and designations in the various drawings indicate like elements.

### DETAILED DESCRIPTION

Semiconductor industry is driven by the need to produce smaller and faster chips. The scaling of DRAM devices faces many challenges. For example, the fabrication process has advanced from an 18 nanometer (nm) process and a 15 nm process to a 10 nm process. However, the increased density of memory cells in a chip and the Row hammer effect may cause disturbance errors. Therefore, advanced techniques for mitigating these problems and improving the scaling of the DRAM devices are desired. To reduce size of memory devices and increase the memory cell density, vertical transistors can be used to replace planar transistors in memory cells of the memory devices. The planar transistors in the memory cells may have a horizontal structure with buried word lines in a substrate and bit lines above the substrate. A planar transistor may occupy a larger area in a memory cell because a source and a drain of the planar transistor are disposed laterally at different locations. In contrast, a vertical transistor usually has a semiconductor body extending vertically. A source and a drain of the vertical transistor may be disposed at two ends of the semiconductor body. Thus, replacing the planar transistor in the memory cells with the vertical transistors can reduce the occupied area of each memory cell and simplify layout of the interconnected structures of the memory cells, the word lines, and the bit lines.

Implementations of the present disclosure can provide one or more of the following technical advantages and/or benefits. A gate oxide layer of a metal-oxide-semiconductor field-effect transistor (MOSFET) turns to a conductive channel when receiving a breakdown voltage. Thus, an anti-fuse storage structure (e.g., anti-fuse capacitor) of a one-time programmable (OTP) memory cell can be implemented as a MOSFET. A vertical transistor is suitable for serving as such an anti-fuse storage structure since a thickness of a gate oxide layer of the vertical transistor can be precisely controlled during manufacturing process. The present disclosure can reduce a chip size of a memory device having an array wafer and a complementary metal-oxide-semiconductor (CMOS) wafer occupying separate structures and being bonded through a hybrid bonding structure. Specifically, a part of an OTP memory cell array (e.g., a peripheral circuit of the memory device) can be relocated from the CMOS wafer to the array wafer and can be implemented as vertical transistors in the array wafer, thereby reducing the area occupied by the peripheral circuit. Furthermore, anti-fuse storage structures and access transistors of the OTP memory cell array can be coupled through the hybrid bonding structure. As such, interferences caused by parasitic capacitance and parasitic resistance can be mitigated and the performance of the memory device can be improved.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

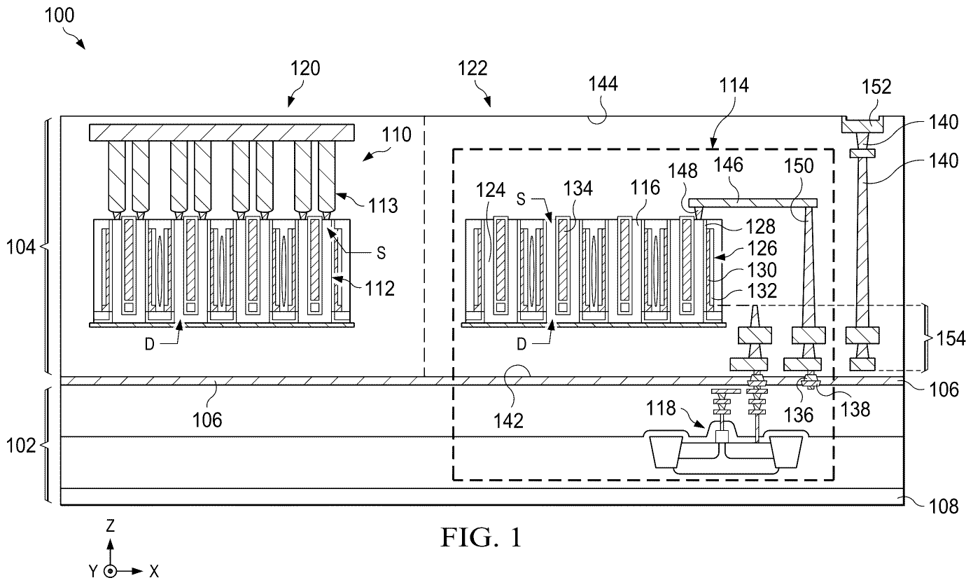

FIG. 1 illustrates a side view of a cross-section of an example semiconductor device 100, according to some aspects of the present disclosure. In some implementations, semiconductor device 100 can be a memory device such as a dynamic random-access memory (DRAM) device.

It is noted that X, Y, and Z axes (also referred to as X, Y, and Z directions) are included in FIG. 1 to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

Semiconductor device 100 is a bonded chip including a semiconductor structure 102 and a semiconductor structure 104 stacked over semiconductor structure 102. Semiconductor structures 102 and 104 can be jointed at a bonding structure 106 (also referred to as a bonding layer or a bonding interface) therebetween, according to some implementations. As shown in FIG. 1, semiconductor structure 104 can include one or more memory cell arrays 110. Each memory cell (e.g., DRAM cell) in memory cell array 110 can include a vertical transistor 112 extending along a vertical direction (e.g., the Z direction) and a storage structure 113 (e.g., a capacitor) coupled to the vertical transistor 112 in the vertical direction. As shown in FIG. 1, semiconductor structure 102 can include a substrate 108, which can include silicon (e.g., single crystalline silicon, c-Si), SiGe, GaAs, Ge, SOI, or any other suitable materials.

In some implementations, semiconductor structure 104 is referred to as an array wafer of semiconductor device 100, and semiconductor structure 102 is referred to as a complementary metal-oxide-semiconductor (CMOS) wafer of semiconductor device 100. Semiconductor structure 102 can be bonded to semiconductor structure 104 in a face-to-face manner through bonding structure 106 extending along the X-Y plane. In some implementations, bonding structure 106 is disposed between semiconductor structures 102 and 104 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding structure 106 can include a bonding layer in semiconductor structure 102 and a bonding layer in semiconductor structure 104 (not shown in FIG. 1). The bonding layer in semiconductor structure 102 can include bonding contacts 138 and dielectrics electrically isolating bonding contacts 138. The bonding layer in semiconductor structure 104 can include bonding contacts 136 and dielectrics electrically isolating bonding contacts 136. Each of bonding contacts 136 and 138 can include conductive materials including, but not limited to, tungsten (W), cobalt (Co), copper (Cu), aluminum (Al), silicides, or any combination thereof.

Semiconductor device 100 further includes a peripheral circuit in either semiconductor structure 102, or semiconductor structure 104, or both. In some implementations, the peripheral circuit is configured to control and sense the memory cell arrays 110. The peripheral circuit can be any suitable digital, analog, and/or mixed-signal control and sensing circuits used for facilitating the semiconductor device 100 including, but not limited to, a page buffer, a decoder (e.g., a row decoder and a column decoder), a sense amplifier, a driver (e.g., a word line driver), a charge pump, a current or voltage reference, or any active or passive components of the circuit (e.g., transistors, diodes, resistors, or capacitors).

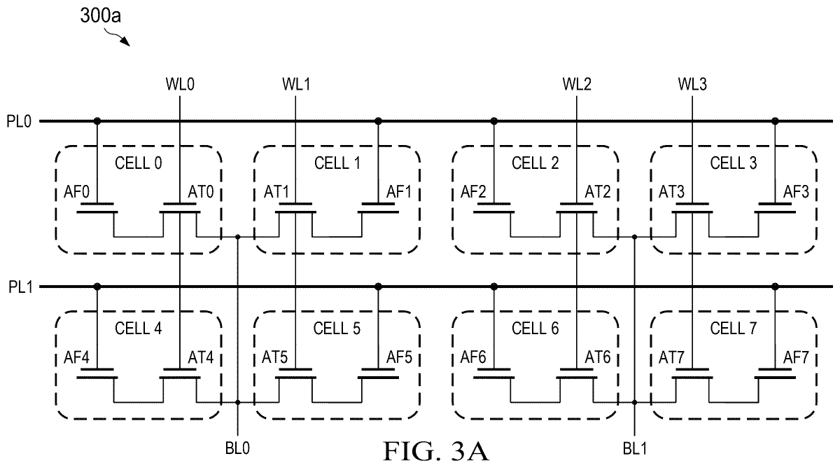

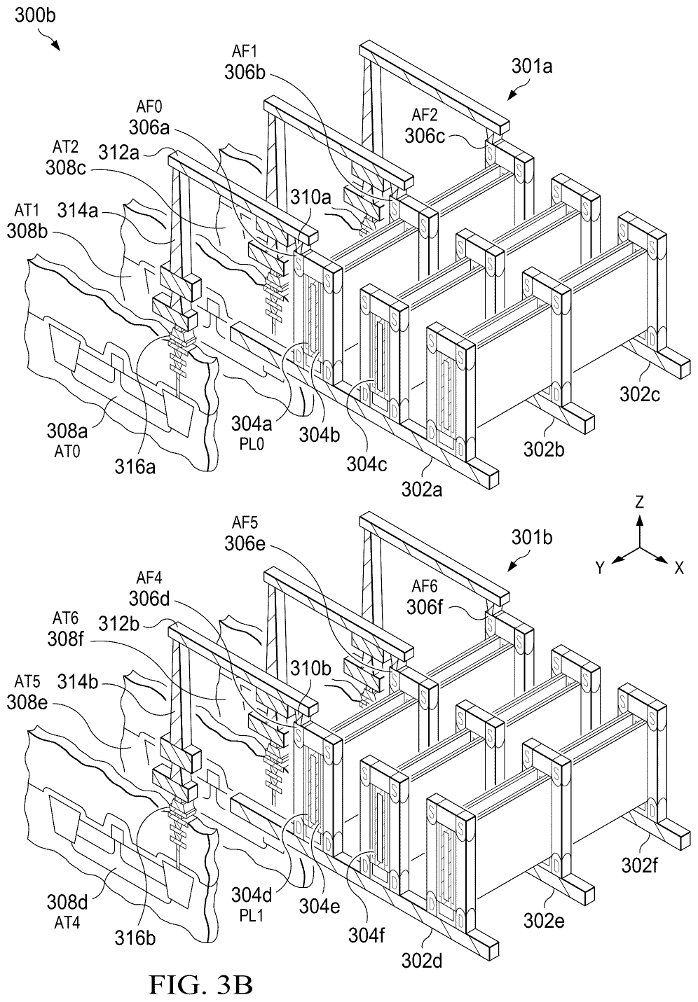

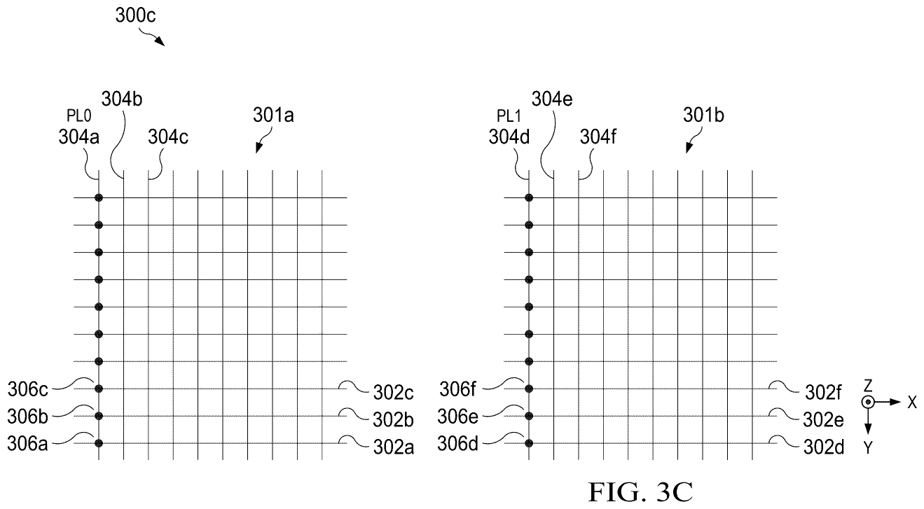

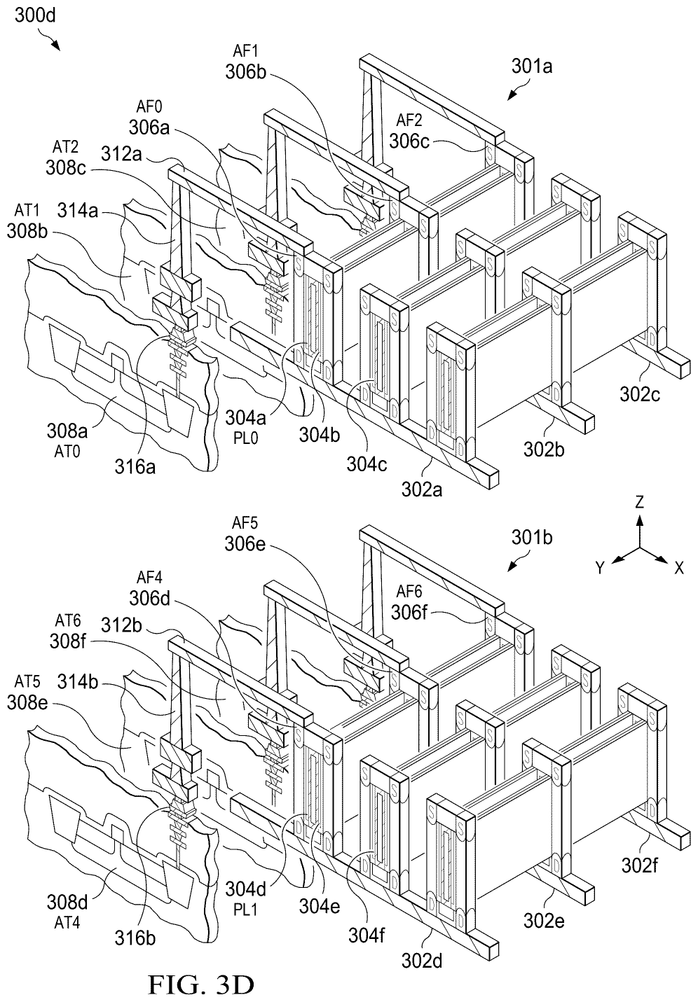

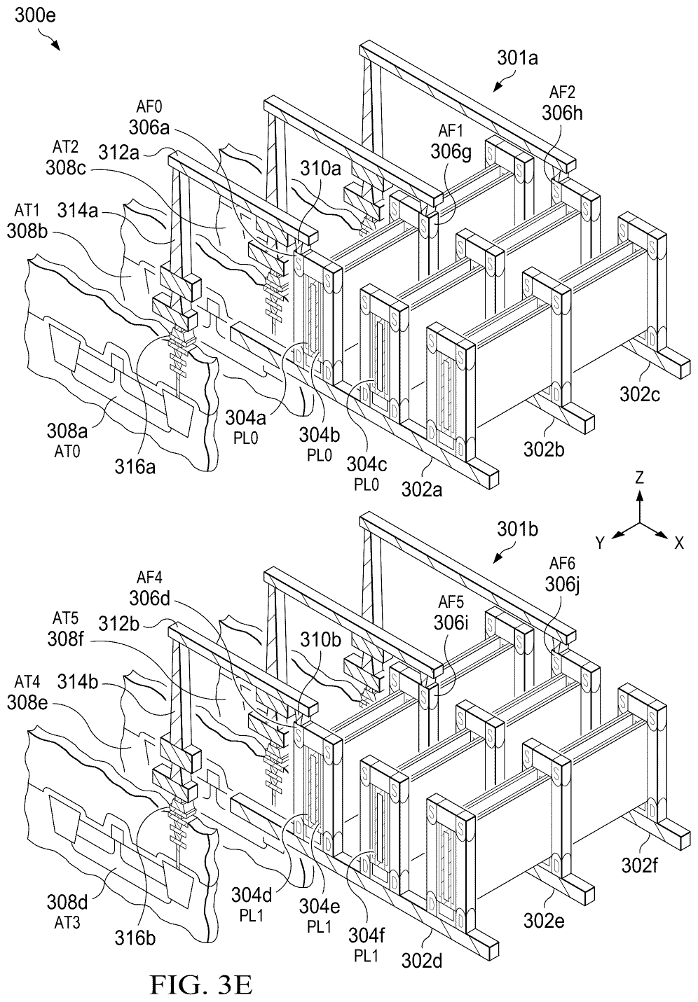

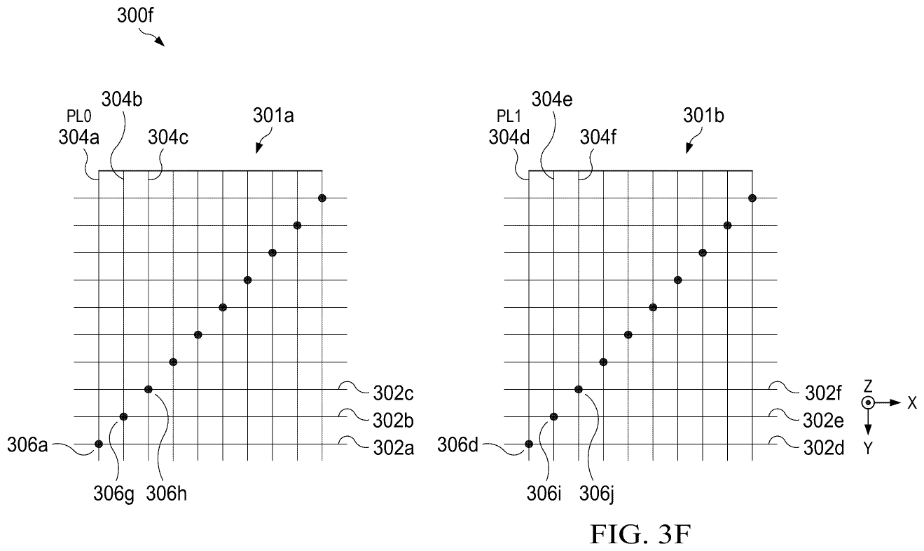

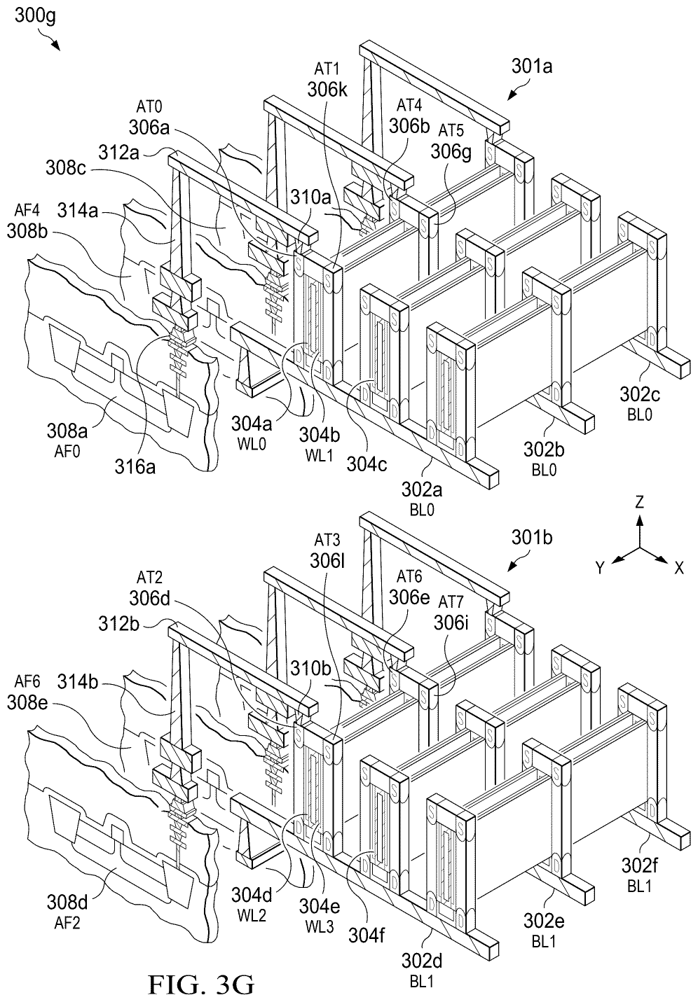

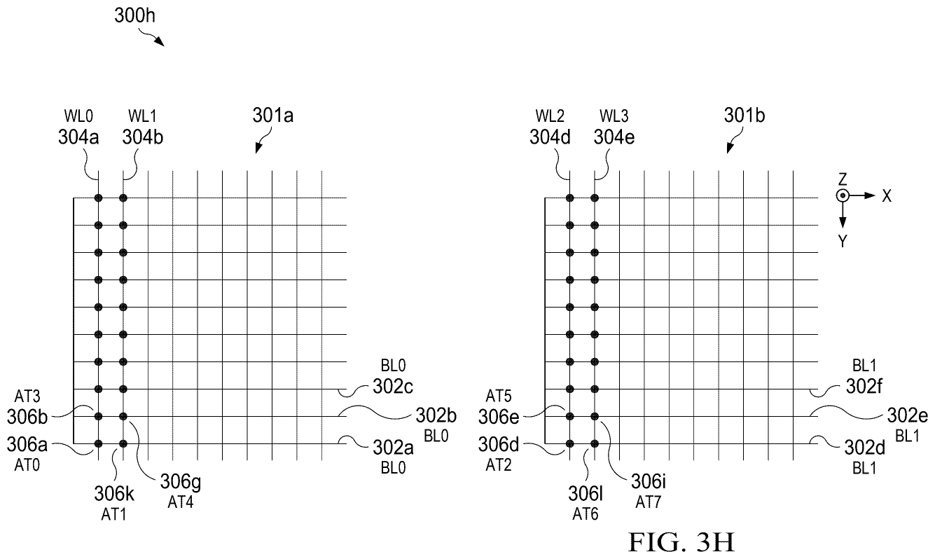

In some implementations, the peripheral circuit includes one or more one-time programmable (OTP) memory cell arrays 114. OTP memory cell arrays 114 can include vertical transistors 116 in semiconductor structure 104 and transistors 118 in semiconductor structure 102. In some implementations, transistors 118 are planar transistors. Each OTP memory cell in OTP memory cell arrays 114 includes one vertical transistor 116 and one transistor 118 coupled together. As shown in FIG. 1, a terminal (a source or drain) of vertical transistor 116 can be coupled to transistor 118 (e.g., a source or drain of transistor 118) through connection lines (e.g., 146) extending along the horizontal direction and contact structures (e.g., 148 and 150) extending along the vertical direction. In some implementations, as described with further details with respect to FIGS. 3B-3F, vertical transistor 116 is an anti-fuse structure (e.g., anti-fuse capacitor) of the OTP memory cell, and transistor 118 coupled to vertical transistor 116 is an access transistor of the OTP memory cell. In some other implementations, as described with further details with respect to FIGS. 3G-3H, vertical transistor 116 can be the access transistor of the OTP memory cell, and transistor 118 coupled to vertical transistor 116 can be the anti-fuse structure of the OTP memory cell.

Memory cell arrays 110 can be located in an area 120 of semiconductor structure 104. Area 120 can be referred to as an array area. Vertical transistors 116 can be located in an area 122 of semiconductor structure 104. Area 122 can be referred to as a dummy area or a peripheral area. Area 122 can be adjacent to area 120 along the X direction. In some implementations, vertical transistors 112 in memory cell arrays 110 and vertical transistors 116 are formed during the same vertical transistor fabrication process.

As shown in FIG. 1, Vertical transistor 116 includes a semiconductor body 124 extending vertically (in the z-direction) above a substrate where it is located (not shown in FIG. 1). It should be appreciated that semiconductor body 124 may have any suitable 3D shape, such as polyhedron shapes or a cylinder shape. That is, the cross-section of semiconductor body 124 in the plan view (e.g., in the x-y plane) can have a square shape, a rectangular shape (or a trapezoidal shape), a circular (or an oval shape), or any other suitable shapes. In some implementations, semiconductor body 124 can be formed from the substrate (e.g., by etching or epitaxy) and thus, has the same semiconductor material (e.g., silicon crystalline silicon) as the substrate (e.g., a silicon substrate).

As shown in FIG. 1, vertical transistor 116 can also include a gate structure 126 in contact with one or more sides of semiconductor body 124. Gate structure 126 extends along a horizontal direction (e.g., the Y direction) perpendicular to the X direction and the Z direction. Gate structure 126 can include a gate dielectric 128 over one or more sides of semiconductor body 124. Gate structure 126 can also include a gate electrode 132 over and in contact with gate dielectric 128. Gate dielectric 128 can include any suitable dielectric materials, such as silicon oxide, silicon nitride, silicon oxynitride, or high-k dielectrics. Gate electrode 132 can include any suitable conductive materials, such as polysilicon, metals (e.g., W, Cu, Al, etc.), metal compounds (e.g., titanium nitride (TiN), tantalum nitride (TaN), etc.), or silicides. For example, gate electrode 132 may include doped polysilicon, i.e., a gate poly. In some implementations, as shown in FIG. 1, gate structure 126 can include a TiN layer (e.g., layer 130) between gate dielectric 128 and gate electrode 132 (e.g., a W layer).

Vertical transistor 116 can further include a pair of a source and a drain (S/D, dope regions, a.k.a., source electrode and drain electrode) formed at the two ends of semiconductor body 124 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 126 in the vertical direction (the z-direction). In planar transistors and some lateral multiple-gate transistors (e.g., fin field-effect transistor (FinFET)), the active regions, such as semiconductor bodies (e.g., Fins), extend laterally (in the X-Y plane), and the source and the drain are disposed at different locations in the same lateral plane (the X-Y plane). In contrast, in vertical transistor 116, semiconductor body 124 extends vertically (in the Z-direction), and the source and the drain are disposed in the different lateral planes, according to some implementations. In some implementations, the source and the drain are formed at two ends of semiconductor body 124 in the vertical direction (the Z-direction), respectively, thereby being overlapped in the plan view. As a result, the area (in the X-Y plane) occupied by vertical transistor 116 can be reduced compared with planar transistor and lateral multiple-gate transistors. Also, the metal wiring coupled to vertical transistor 116 can be simplified.

In some implementations, vertical transistor 116 is a multi-gate transistor. That is, gate structure 126 can be in contact with more than one side of semiconductor body 124. In some other implementations, as shown in FIG. 1 and some other figures of this disclosure, vertical transistor 116 is a single-gate transistor. That is, gate structure 126 may be in contact with a single side of semiconductor body 124, for example, for the purpose of increasing the transistor and memory cell density. In some implementations, as shown in FIG. 1, a conductive layer 134 (e.g., Tiso metal) is located between two adjacent vertical transistors 116. Conductive layer 134 can be configured to have a low voltage level, thereby improving the coupling effect between the two adjacent vertical transistors.

In some implementations, as shown in FIG. 1, semiconductor device 100 further includes one or more contact structures 140 that extend along the Z direction in semiconductor structure 104 and one or more contact pads 152 that are close to surface 144 of semiconductor structure 104 and extend in the X-Y plane. Contact structures 140 can be coupled to contact pads 152 for pad-out, which can provide connections from the inside of semiconductor device 100 (e.g., through interconnect layer 154 as described below) to an external component (e.g., on a surface 144 of semiconductor structure 104).

In some implementations, semiconductor structure 104 further includes one or more interconnect layers (e.g., 154 as shown in FIG. 1) for routing electrical signals between different components of semiconductor structure 104. For example, interconnect layer 154 can connect each of contact structure 150 and gate structure 126 to a corresponding bonding contact (e.g., one of bonding contacts 136) on surface 142 of semiconductor structure 104, and can connect a suitable component to contact structures 140 for pad-out. Each interconnect layer can include lateral interconnect lines and vertical interconnect structures such as vertical interconnect access (VIA) contacts or contact structures. As used herein, the term “interconnects” can broadly include any suitable types of interconnects, such as middle-end-of-line (MEOL) interconnects and back-end-of-line (BEOL) interconnects. The interconnect lines and VIA contacts in the interconnect layer can include conductive materials including, but not limited to, W, Co, Cu, Al, silicides, or any combination thereof.

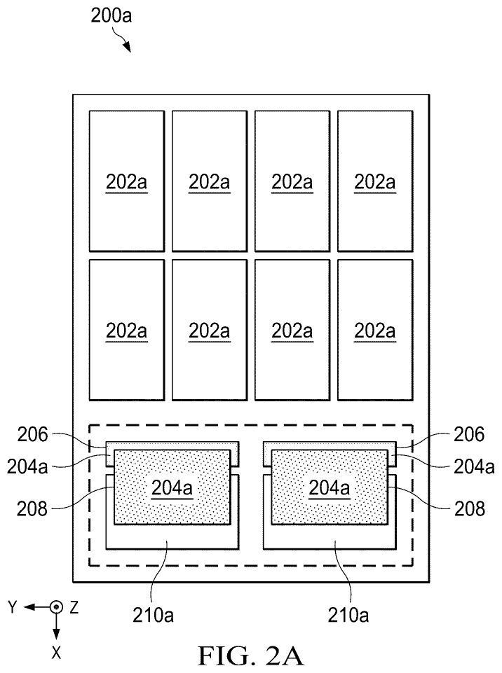

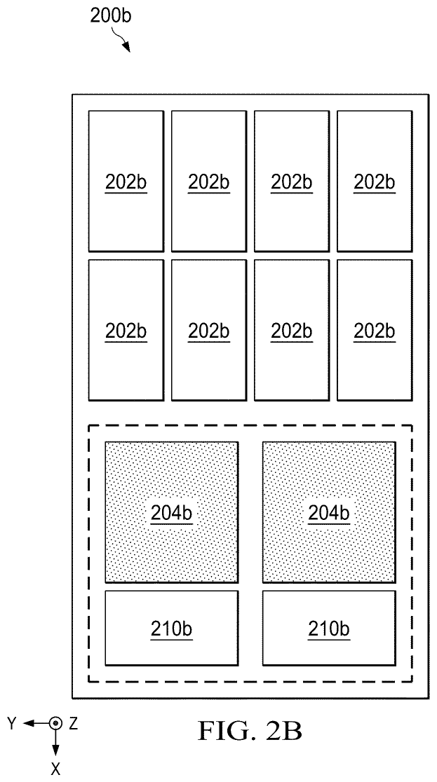

FIGS. 2A-2B illustrate top views of example semiconductor devices 200a and 200b respectively, according to some aspects of the present disclosure. Semiconductor device 200a can be an example of semiconductor device 100 of FIG. 1. Semiconductor device 200a includes a CMOS wafer and an array wafer bonded together (not shown in FIG. 2A). Semiconductor device 200a includes memory cell arrays 202a in the array wafer. Memory cell arrays 202a can be an example of memory cell arrays 110 of FIG. 1. Semiconductor device 200a further includes OTP memory cell arrays 204a, which can be an example of OTP memory cell arrays 114 of FIG. 1. Semiconductor device 200a further includes control circuits 210a for OTP memory cell arrays 204a. In some implementations, each of OTP memory cell arrays 204a can be split into two parts 206 and 208, one in the array wafer and another in the CMOS wafer. Part 208 can include vertical transistors (e.g., vertical transistors 116 of FIG. 1) and is located in the array wafer. Part 206 (e.g., transistors 118 of FIG. 1) is located in the CMOS wafer. Control circuits 210a for OTP memory cell arrays 204a are in the CMOS wafer of semiconductor device 200a.

Semiconductor device 200b can be another semiconductor device (e.g., a DRAM device) formed in a different structure. Semiconductor device 200b also includes a CMOS wafer and an array wafer bonded together (not shown in FIG. 2B). Semiconductor device 200b includes memory cell arrays 202b in the array wafer and OTP memory cell arrays 204b in the CMOS wafer. The CMOS wafer of semiconductor device 200b further includes control circuits 210b for OTP memory cell arrays 204b.

Structures of semiconductor devices 200a and 200b are different in that, a part of OTP memory cell arrays (e.g., parts 208 of OTP memory cell arrays 204a) in semiconductor device 200a are located in the array wafer of the semiconductor device 200a, while OTP memory cell arrays in semiconductor device 200b are located in the CMOS wafer of the semiconductor device 200b. As a result, the peripheral circuit in semiconductor device 200b occupies more chip space (e.g., in the X-Y plane). In other words, compared to semiconductor device 200b, the chip size of semiconductor device 200a is reduced by relocating a part of the OTP memory cell arrays from the CMOS wafer of semiconductor device 200a to the array wafer of semiconductor device 200a.

FIGS. 3A-3H illustrate example OTP memory cell arrays, according to some aspects of the present disclosure. FIG. 3A illustrates a schematic diagram 300a of an example OTP memory cell array, according to some aspects of the present disclosure. The OTP memory cell array illustrated by diagram 300a includes OTP memory cells 0, 1, 2, and 3 coupled to program line (PL) 0 and OTP memory cells 4, 5, 6, and 7 coupled to PL 1. Diagram 300a further includes word lines (WLs) 0, 1, 2, and 3 and bit lines (BLs) 0 and 1. OTP memory cells 0-7 can be 2-T OTP cells. That is, each OTP memory cell includes an access transistor and an anti-fuse structure coupled together. The anti-fuse structure can be an anti-fuse capacitor and can be, for example, implemented by a N-type metal-oxide-semiconductor (NMOS) transistor. OTP memory cell 0 includes an access transistor 0 and an anti-fuse structure 0. A terminal (e.g., a source) of access transistor 0 is coupled to a terminal (e.g., a source) of anti-fuse structure 0. Another terminal (e.g., a drain) of access transistor 0 is coupled to a bit line (e.g., BL0 as shown in FIG. 3A). Another terminal of anti-fuse structure 0 is floating. A gate of anti-fuse structure 0 is coupled to a program line (e.g., PL 0), and a gate of access transistor 0 is coupled to a word line (e.g., WL0). OTP memory cells 1-7 have structures similar to OTP memory cell 0. OTP memory cells 0, 1, 4, and 5 are coupled to BL 0, and OTP memory cells 2, 3, 6, and 7 are coupled to BL 1. In addition, OTP memory cells 0 and 4 are coupled to WL0 through gates of their respective access transistors, OTP memory cells 1 and 5 are coupled to WL1 through gates of their respective access transistors, OTP memory cells 2 and 6 are coupled to WL2 through gates of their respective access transistors, and OTP memory cells 3 and 7 are coupled to WL3 through gates of their respective access transistors.

It is understood that while diagram 300a of FIG. 3A illustrates two PLs, two BLs, 4 WLs and eight OTP memory cells, an OTP memory cell array can include any suitable number of PLS, BLs, WLs, and OTP memory cells.

FIG. 3B illustrates a perspective view of an example OTP memory cell array 300b formed based on the schematic diagram 300a of FIG. 3A, according to some aspects of the present disclosure. FIG. 3C illustrates a top view 300c of OTP memory cell array 300b. OTP memory cell array 300b can be used to form a memory device (e.g., semiconductor device 100 of FIG. 1). OTP memory cell array 300b includes a vertical transistor array 301a, a vertical transistor array 301b, a planar transistor array 303a, and a planar transistor array 303b. Each of vertical transistor arrays 301a and 301b can also be referred to as a vertical transistor block. In some implementations, vertical transistor arrays 301a and 301b can be located in an array wafer (e.g., semiconductor structure 104 of FIG. 1) of the memory device, and planar transistor arrays 303a and 303b can be located in a CMOS wafer (e.g., semiconductor structure 102 of FIG. 1) of the memory device.

Vertical transistor array 301a includes an array of vertical transistors (such as vertical transistors 306a, 306b, and 306c, etc.) extending along the Z direction. Each row of (arranged along the X direction) vertical transistors in vertical transistor array 301a have their drains coupled to a connection line extending along the X direction (also referred to as a terminal line). Each column of vertical transistors in vertical transistor array 301a have their gates coupled to a connection line extending along the Y direction (also referred to as a gate line). As shown in FIG. 3B and FIG. 3C, each vertical transistor in vertical transistor array 301a is located at an intersection of a corresponding terminal line and a corresponding gate line. The terminal lines of vertical transistor array 301a include 302a, 302b, and 302c. The gate lines of vertical transistor array 301a include 304a, 304b, and 304c.

Similarly, vertical transistor array 301b also includes an array of vertical transistors (such as vertical transistors 306d, 306c, and 306f, etc.) extending along the Z direction. Each row of (arranged along the X direction) vertical transistors in vertical transistor array 301b have their drains coupled to a terminal line extending along the X direction. Each column of vertical transistors in vertical transistor array 301b have their gates coupled to a gate line extending along the Y direction. As shown in FIG. 3B and FIG. 3C, each vertical transistor in vertical transistor array 301b is located at an intersection of a corresponding terminal line and a corresponding gate line. The terminal lines of vertical transistor array 301b include 302d, 302e, and 302f. The gate lines of vertical transistor array 301b include 304d, 304c, and 304f. In some implementations, the terminal lines and gate lines in vertical transistor arrays 301a and 301b are made of conductive materials including, but not limited to W, Co, Cu, Al, TIN, TaN, polysilicon, silicides, or any combination thereof. Each terminal line in vertical transistor arrays 301a and 301b is floating.

In some implementations, anti-fuse structures that have their gates coupled to the same PL in diagram 300a can be implemented using a column of vertical transistors (coupled to the same gate line through their gates) in a vertical transistor array. For example, gate line 304a in vertical transistor array 301a of OTP memory cell array 300b can be PL 0 of diagram 300a. Vertical transistor 306a in vertical transistor array 301a of OTP memory cell array 300b can be anti-fuse structure 0 of diagram 300a. Vertical transistor 306b in vertical transistor array 301a of OTP memory cell array 300b can be anti-fuse structure 1 of diagram 300a. Vertical transistor 306c in vertical transistor array 301a of OTP memory cell array 300b can be anti-fuse structure 2 of diagram 300a. Planar transistor 308a (in the CMOS wafer) in OTP memory cell array 300b can be access transistor 0 of diagram 300a. Planar transistor 308b (in the CMOS wafer) in OTP memory cell array 300b can be access transistor 1 of diagram 300a. Planar transistor 308c (in the CMOS wafer) in OTP memory cell array 300b can be access transistor 2 of diagram 300a. As shown in FIG. 3B, a terminal (e.g., a source) of each of vertical transistors 306a, 306b, and 306c is coupled to a terminal (e.g., a source) of a respective planar transistor of planar transistors 308a, 308b, and 308c through a contact structure (e.g., 310a) extending along the Z direction, a connection line (e.g., 312a) extending in the X-Y plane (e.g., along the X direction), another contact structure (e.g., 314a) extending along the Z direction, and bonding contacts (e.g., 316a) in a hybrid bonding structure between the array wafer and the CMOS wafer.

Similarly, gate line 304d in vertical transistor array 301b of OTP memory cell array 300b can be PL 1 of diagram 300a. Vertical transistor 306d in vertical transistor array 301b of in OTP memory cell array 300b can be anti-fuse structure 4 of diagram 300a. Vertical transistor 306e in vertical transistor array 301b of OTP memory cell array 300b can be anti-fuse structure 5 of diagram 300a. Vertical transistor 306f in vertical transistor array 301b of OTP memory cell array 300b can be anti-fuse structure 6 of diagram 300a. Planar transistor 308d (in the CMOS wafer) in OTP memory cell array 300b can be access transistor 4 of diagram 300a. Planar transistor 308e (in the CMOS wafer) in OTP memory cell array 300b can be access transistor 5 of diagram 300a. Planar transistor 308f (in the CMOS wafer) in OTP memory cell array 300b can be access transistor 6 of diagram 300a. As shown in FIG. 3B, a terminal (e.g., a source) of each of vertical transistors 306d, 306e, and 306f is coupled to a terminal (e.g., a source) of a respective planar transistor of planar transistors 308d, 308c, and 308f through a contact structure (e.g., 310b) extending along the Z direction, a connection line (e.g., 312b) extending in the X-Y plane (e.g., along the X direction), another contact structure (e.g., 314b) extending along the Z direction, and bonding contacts (e.g., 316b) in the hybrid bonding structure between the array wafer and the CMOS wafer.

FIG. 3D illustrates a perspective view of another example OTP memory cell array 300d formed based on the schematic diagram 300a of FIG. 3A, according to some aspects of the present disclosure. OTP memory cell array 300d can be used to form a memory device (e.g., semiconductor device 100 of FIG. 1). OTP memory cell array 300d has the same top view 300c as OTP memory cell array 300b. Similar to OTP memory cell array 300b, OTP memory cell array 300d also includes vertical transistor arrays 301a and 301b in an array wafer (e.g., semiconductor structure 104 of FIG. 1) of the memory device and planar transistor arrays 303a and 303b in a CMOS wafer (e.g., semiconductor structure 102 of FIG. 1) of the memory device. OTP memory cell array 300d differs from OTP memory cell array 300b in that, a source of each vertical transistor in OTP memory cell array 300d that is coupled to a corresponding planar transistor is directly coupled to a connection line extending in the X-Y plane, rather than being coupled to the connection line through a contact structure extending in the Z direction. For example, a source of vertical transistor 306a in vertical transistor array 301a is directly coupled to connection line 312a extending in the X-Y plane (e.g., along the X direction). Similarly, a source of vertical transistor 306d in vertical transistor array 301b is directly coupled to connection line 312b extending in the X-Y plane (e.g., along the X direction). As such, connections lines 312a and 312b and storage structures of a memory cell array that is also located in the array wafer of the memory device can be formed in the same fabrication process (e.g., using double patterning), thereby reducing manufacturing cost.

FIG. 3E illustrates a perspective view of another example OTP memory cell array 300c formed based on the schematic diagram 300a of FIG. 3A, according to some aspects of the present disclosure. FIG. 3F illustrates a top view 300f of OTP memory cell array 300e. OTP memory cell array 300e can be used to form a memory device (e.g., semiconductor device 100 of FIG. 1). OTP memory cell array 300e also includes vertical transistor arrays 301a and 301b in an array wafer (e.g., semiconductor structure 104 of FIG. 1) of the memory device and planar transistor arrays 303a and 303b in a CMOS wafer (e.g., semiconductor structure 102 of FIG. 1) of the memory device.

In some implementations, anti-fuse structures that have their gates coupled to the same PL in diagram 300a can be implemented using vertical transistors on different columns of a vertical transistor array. For example, gate lines (e.g., 304a, 304b, and 304c) in vertical transistor array 301a of OTP memory cell array 300e can be connected (as shown in FIG. 3F) and can be PL 0 of diagram 300a. In some instances, the anti-fuse structures whose gates are coupled to PL 0 of diagram 300a can be arranged on a diagonal of the vertical transistor array. As shown in FIG. 3F, for instance, vertical transistor 306a in vertical transistor array 301a of OTP memory cell array 300b can be anti-fuse structure 0 of diagram 300a. Vertical transistor 306g in vertical transistor array 301a of OTP memory cell array 300b can be anti-fuse structure 1 of diagram 300a. Vertical transistor 306h in vertical transistor array 301a of OTP memory cell array 300b can be anti-fuse structure 2 of diagram 300a. Planar transistor 308a (in the CMOS wafer) in OTP memory cell array 300b can be access transistor 0 of diagram 300a. Planar transistor 308b (in the CMOS wafer) in OTP memory cell array 300b can be access transistor 1 of diagram 300a. Planar transistor 308c (in the CMOS wafer) in OTP memory cell array 300b can be access transistor 2 of diagram 300a. As shown in FIG. 3B, a terminal (e.g., a source) of each of vertical transistors 306a, 306g, and 306h is coupled to a terminal (e.g., a source) of a respective planar transistor of planar transistors 308a, 308b, and 308c through a contact structure (e.g., 310a) extending along the Z direction, a connection line (e.g., 312a) extending in the X-Y plane (e.g., along the X direction), another contact structure (e.g., 314a) extending along the Z direction, and bonding contacts (e.g., 316a) in a hybrid bonding structure between the array wafer and the CMOS wafer.

Similarly, gate lines (e.g., 304d, 304c, and 304f) in vertical transistor array 301b of OTP memory cell array 300e can be connected (as shown in FIG. 3F) and can be PL 1 of diagram 300a. Vertical transistor 306d in vertical transistor array 301b of in OTP memory cell array 300e can be anti-fuse structure 4 of diagram 300a. Vertical transistor 306i in vertical transistor array 301b of OTP memory cell array 300e can be anti-fuse structure 5 of diagram 300a. Vertical transistor 306j in vertical transistor array 301b of OTP memory cell array 300e can be anti-fuse structure 6 of diagram 300a. Planar transistor 308d (in the CMOS wafer) in OTP memory cell array 300e can be access transistor 4 of diagram 300a. Planar transistor 308e (in the CMOS wafer) in OTP memory cell array 300e can be access transistor 5 of diagram 300a. Planar transistor 308f (in the CMOS wafer) in OTP memory cell array 300e can be access transistor 6 of diagram 300a. As shown in FIG. 3E, a terminal (e.g., a source) of each of vertical transistors 306d, 306i, and 306j is coupled to a terminal (e.g., a source) of a respective planar transistor of planar transistors 308d, 308c, and 308f through a contact structure (e.g., 310b) extending along the Z direction, a connection line (e.g., 312b) extending in the X-Y plane (e.g., along the X direction), another contact structure (e.g., 314b) extending along the Z direction, and bonding contacts (e.g., 316b) in the hybrid bonding structure between the array wafer and the CMOS wafer.

In some implementations, spreading out vertical transistors that form the OTP memory cell array along the X direction (as shown in FIGS. 3E and 3F) can create more space and make it easier to arrange interconnects between the vertical transistors and other components.

FIG. 3G illustrates a perspective view of another example OTP memory cell array 300g formed based on the schematic diagram 300a of FIG. 3A, according to some aspects of the present disclosure. FIG. 3H illustrates a top view 300h of OTP memory cell array 300g. OTP memory cell array 300g can be used to form a memory device (e.g., semiconductor device 100 of FIG. 1). OTP memory cell array 300g also includes vertical transistor arrays 301a and 301b in an array wafer (e.g., semiconductor structure 104 of FIG. 1) of the memory device and planar transistor arrays 303a and 303b in a CMOS wafer (e.g., semiconductor structure 102 of FIG. 1) of the memory device.

In some implementations, access transistors in diagram 300a can be implemented using vertical transistors in the array wafer, and anti-fuse structures in diagram 300a can be implemented using planar transistors in the CMOS wafer. Specifically, access transistors that have their terminals (e.g., drains) coupled to the same BL in diagram 300a can be implemented using two adjacent columns of vertical transistors in a vertical transistor array. For example, terminal lines (e.g., 302a, 302b, and 302c) in vertical transistor array 301a of OTP memory cell array 300g can be connected (as shown in FIG. 3H) and can be BL 0 of diagram 300a. The terminal lines in vertical transistor array 301a of OTP memory cell array 300g are still floating. Gate lines 304a and 304b in vertical transistor array 301a of OTP memory cell array 300g can be WL0 and WL1 of diagram 300a, respectively. Vertical transistor 306a in vertical transistor array 301a of OTP memory cell array 300g can be access transistor 0 of diagram 300a. Vertical transistor 306k in vertical transistor array 301a of OTP memory cell array 300g can be access transistor 1 of diagram 300a. Vertical transistor 306b in vertical transistor array 301a of OTP memory cell array 300g can be access transistor 4 of diagram 300a. Vertical transistor 306g in vertical transistor array 301a of OTP memory cell array 300g can be access transistor 5 of diagram 300a. Planar transistor 308a (in the CMOS wafer) in OTP memory cell array 300g can be anti-fuse structure 0 of diagram 300a. Planar transistor 308b (in the CMOS wafer) in OTP memory cell array 300g can be anti-fuse structure 4 of diagram 300a. As shown in FIG. 3G, a terminal (e.g., a source) of each of vertical transistors 306a and 306b is coupled to a terminal (e.g., a source) of a respective planar transistor of planar transistors 308a and 308b through a contact structure (e.g., 310a) extending along the Z direction, a connection line (e.g., 312a) extending in the X-Y plane (e.g., along the X direction), another contact structure (e.g., 314a) extending along the Z direction, and bonding contacts (e.g., 316a) in a hybrid bonding structure between the array wafer and the CMOS wafer.

Similarly, terminal lines (e.g., 302d, 302e, and 302f) in vertical transistor array 301b of OTP memory cell array 300g can be connected (as shown in FIG. 3H) and can be BL 1 of diagram 300a. The terminal lines in vertical transistor array 301b of OTP memory cell array 300g are still floating. Gate lines 304d and 304e in vertical transistor array 301b of OTP memory cell array 300g can be WL2 and WL3 of diagram 300a, respectively. Vertical transistor 306d in vertical transistor array 301b of OTP memory cell array 300g can be access transistor 2 of diagram 300a. Vertical transistor 3061 in vertical transistor array 301b of OTP memory cell array 300g can be access transistor 3 of diagram 300a. Vertical transistor 306e in vertical transistor array 301b of OTP memory cell array 300g can be access transistor 6 of diagram 300a. Vertical transistor 306i in vertical transistor array 301b of OTP memory cell array 300g can be access transistor 7 of diagram 300a. Planar transistor 308d (in the CMOS wafer) in OTP memory cell array 300g can be anti-fuse structure 2 of diagram 300a. Planar transistor 308e (in the CMOS wafer) in OTP memory cell array 300g can be anti-fuse structure 6 of diagram 300a. As shown in FIG. 3G, a terminal (e.g., a source) of each of vertical transistors 306d and 306e is coupled to a terminal (e.g., a source) of a respective planar transistor of planar transistors 308d and 308e through a contact structure (e.g., 310b) extending along the Z direction, a connection line (e.g., 312b) extending in the X-Y plane (e.g., along the X direction), another contact structure (e.g., 314b) extending along the Z direction, and bonding contacts (e.g., 316b) in a hybrid bonding structure between the array wafer and the CMOS wafer.

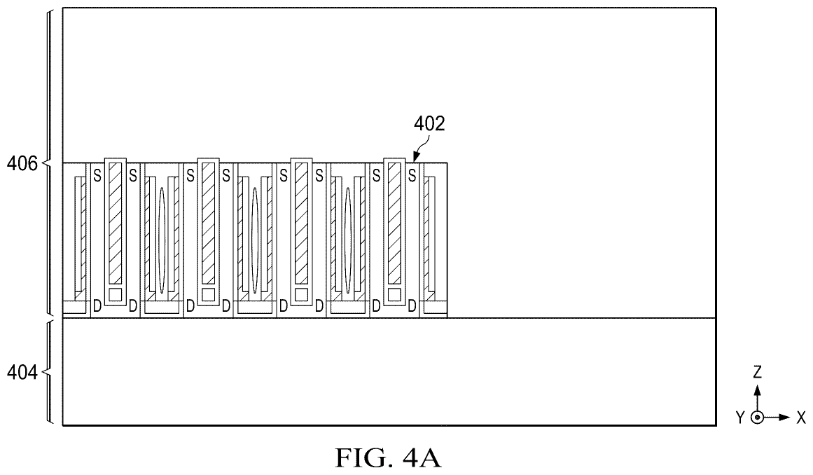

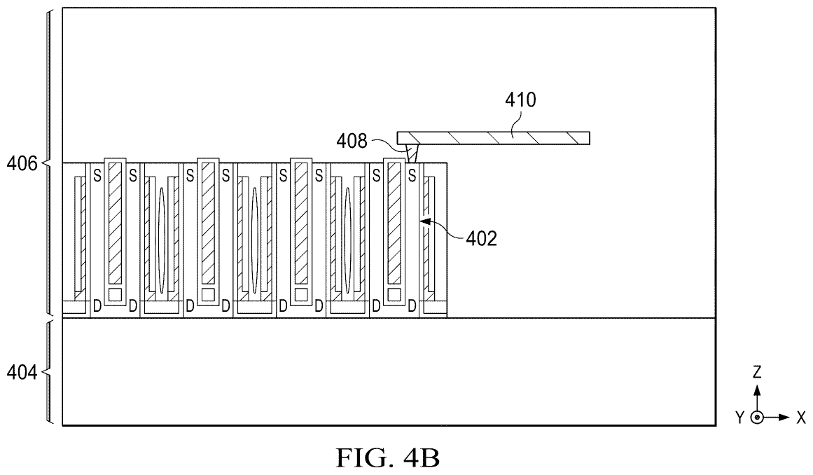

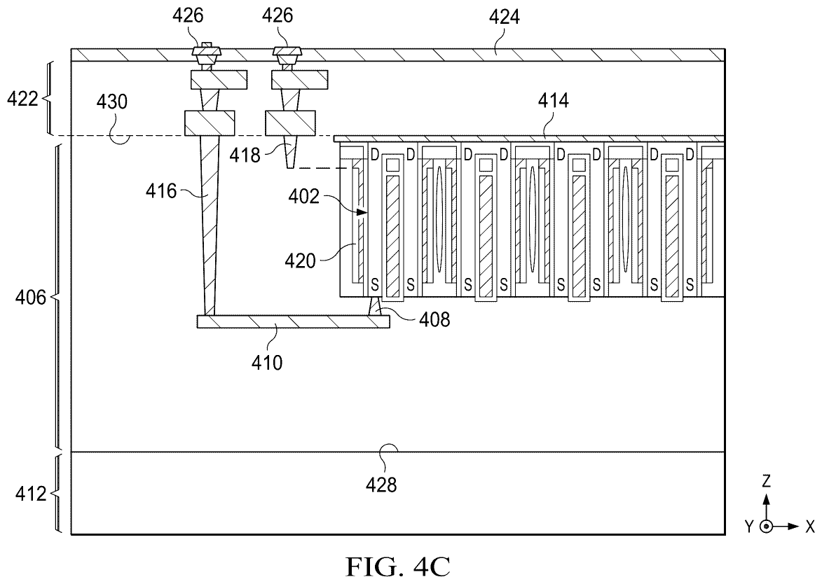

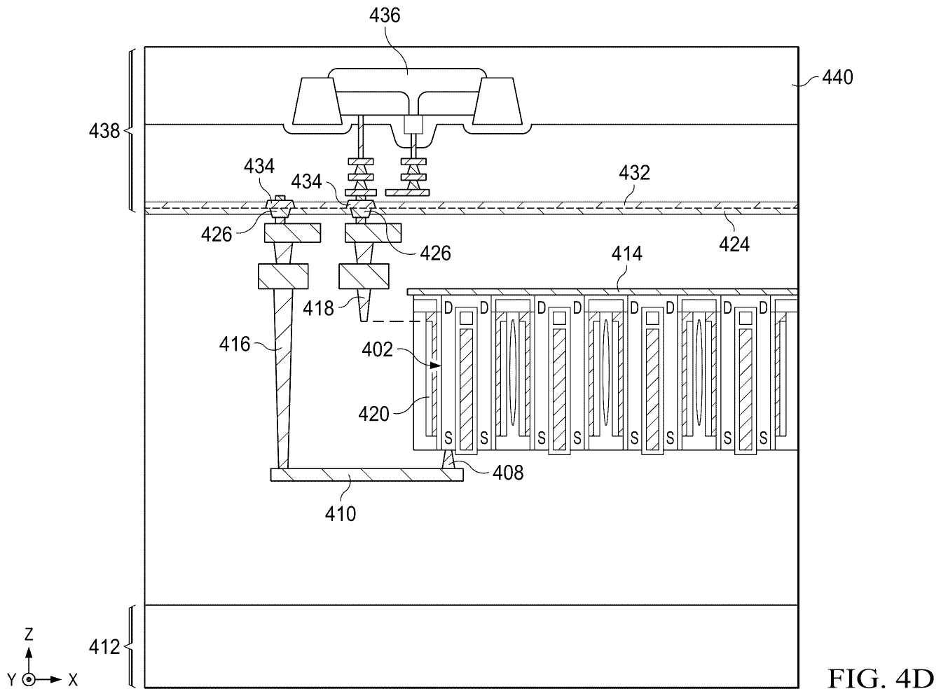

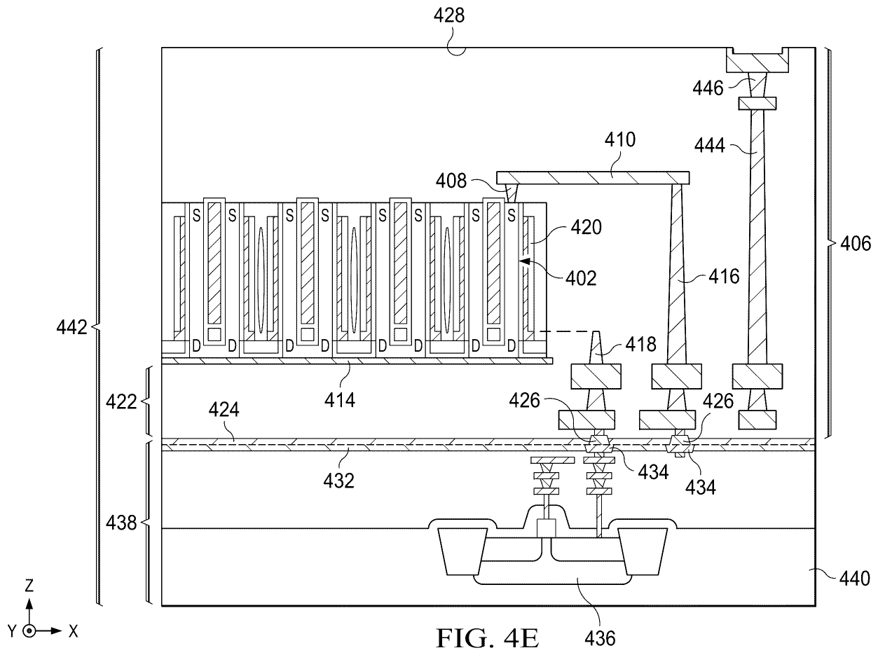

FIGS. 4A-4E illustrate a fabrication process for forming an example semiconductor structure, according to some aspects of the present disclosure. Structures shown in FIGS. 4A-4E can be similar to, or same as, semiconductor device 100 of FIG. 1 and semiconductor device 200a of FIG. 2A, or a structure at an intermediate fabrication process of semiconductor devices 100 and 200a.

As shown in FIG. 4A, an array of vertical transistors 402 are formed on a substrate 404. Each vertical transistor 402 can be an example of vertical transistor 116 of FIG. 1. Another array of vertical transistors (e.g., vertical transistor 112 of FIG. 1, which are not shown in FIG. 4A) which are used to form DRAM memory cells (e.g., memory cell array 110) also can be formed on the substrate 404. Vertical transistors 402 can be formed in a peripheral area (e.g., area 122 of FIG. 1), and the vertical transistors for forming DRAM memory cells can be formed in an array area (e.g., area 120 of FIG. 1). In some implementations, vertical transistors in both the peripheral area and the array area (including vertical transistors 402 and the vertical transistors for forming DRAM memory cells) can be formed during a same fabrication process. In an example fabrication process of the vertical transistors, semiconductor bodies (e.g., semiconductor body 124 of FIG. 1) of the vertical transistors that extend along the vertical direction (e.g., the Z direction) are formed on the substrate 404 (e.g., by forming trenches extending along the lateral directions (e.g., the X direction and the Y direction) during an etching process). In some implementations, the semiconductor bodies of the vertical transistors can be doped with a dopant (e.g., a P-type dopant or an N-type dopant). The fabrication process of the vertical transistors can further include forming gate structures (e.g., gate structure 126 of FIG. 1) of the vertical transistors by depositing a gate dielectric layer and a conductive layer on each of the semiconductor bodies.

In some implementations, an isolation structure 406 is formed on substrate 404, for example, by depositing a dielectric, such as silicon oxide, using one or more film deposition processes including, but not limited to, chemical vapor deposition (CVD), physical vapor deposition (PVD), atomic layer deposition (ALD), or any combination thereof.

While storage structures (e.g., storage structure 113 of FIG. 1) are formed in the array area and coupled to the vertical transistors in the array area to form the DRAM memory cells, no storage structures are required to be formed in the peripheral area and coupled to the vertical transistors 402. In some implementations, during a fabrication process of the storage structures in the array area, the vertical transistors 402 in the peripheral area can be covered with a mask.

As shown in FIG. 4A, contact structures 408 can be formed and connected to a group of vertical transistors selected from vertical transistors 402 in the peripheral area. Each contact structure 408 can extend along the Z direction and can be connected to a terminal (e.g., a source) of a corresponding vertical transistor of the group of vertical transistors. In some implementations, the group of vertical transistors can be transistors on a column, a diagonal, or two adjacent columns of the array of vertical transistors 402 as described with respect to FIGS. 3A-3G. Contact structures 408 can be formed, for example, by an etching process followed by depositing conductive materials. The etching process can remove a portion of isolation structure 406 to form a hole or a trench so that a terminal of each vertical transistor 402 (e.g., a source, which is an end of the semiconductor body of each vertical transistor 402) is exposed. In addition, connection lines 410 extending along the lateral direction (e.g., in the X-Y plane) can be formed (e.g., using double patterning). Each connection line 410 can be coupled to a corresponding contact structure 408.

As shown in FIG. 4C, substrate 404 can be removed. In some implementations, substrate 404 can be thinned. A carrier wafer 412 can be bonded to surface 428 of isolation structure 406. The bonded carrier wafer 412 and the isolation structure 406 (including vertical transistors 402, contact structures 408, and connection lines 410 in the isolation structure 406) can be flipped upside down. Terminal lines 414 (e.g., terminal lines 302a-302f of FIGS. 3B-3H) can be formed. Each terminal line 414 is connected to a row of vertical transistors of the array of vertical transistors 402. Contact structures 416 and 418 can be formed and connected to connection lines 410 and gate lines 420 (e.g., gate lines 304a-304f of FIGS. 3B-3H) respectively. One or more interconnect layers 422 (e.g., interconnect layers 154 of FIG. 1) are formed on top of surface 430 of isolation structure 406. A bonding layer 424 can be formed on top of interconnect layers 422. Bonding layer 424 can include bonding contacts 426 and dielectrics electrically isolating bonding contacts 426. Interconnect layers 422 can be used, for example, to route electrical signals between contact structures 416 and 418 and bonding contacts 426. In some implementations, as will be described with further details with respect to FIG. 4E, interconnect layers 422 can be used to route electrical signals for pad-out.

As shown in FIG. 4D, a semiconductor structure 438 is stacked on bonding layer 424. Semiconductor structure 438 can be an example of semiconductor structure 102 of FIG. 1. Semiconductor structure 438 includes a substrate 440, transistors 436 (e.g., planar transistors 118 of FIG. 1) and a bonding layer 432. Bonding layer 432 can include bonding contacts 434 and dielectrics electrically isolating bonding contacts 434. The hybrid bonding technology can be used to form bonding between bonding layer 432 and bonding layer 424 and can obtain metal-metal bonding (bonding contacts 426 and 434) and dielectric-dielectric bonding (dielectrics in each of bonding layers 424 and 432) simultaneously. Transistors 436 and some selected vertical transistors 402 can be coupled through bonding contacts 426 and 434 and form one or more OTP memory cell arrays (e.g., OTP memory cell arrays 114 of FIG. 1). Each transistor 436 and a corresponding vertical transistor 402 can form an OTP memory cell of the one or more OTP memory cell arrays. In some implementations, the transistor 436 can be an access transistor of the OTP memory cell, and the corresponding vertical transistor 402 can be an anti-fuse structure of the OTP memory cell (e.g., as described with respect to FIGS. 3B-3F). In some other implementations, the transistor 436 can be an anti-fuse structure of the OTP memory cell, and the corresponding vertical transistor 402 can be an access transistor of the OTP memory cell (e.g., as described with respect to FIGS. 3G-3H).

As shown in FIG. 4E, carrier wafer 412 can be removed or de-bonded. A semiconductor structure 442 that includes vertical transistors 402, isolation structure 406, interconnect layers 422, bonding layer 424, and semiconductor structure 438 is formed. The semiconductor structure 442 can be flipped upside down and can use substrate 440 of semiconductor structure 438 as a carrier structure. The semiconductor structure 442 can be an example of semiconductor device 100 of FIG. 1. In some implementations, as shown in FIG. 4E, semiconductor structure 442 further includes one or more contact structures 444 (e.g., contact structures 140 of FIG. 1) that extend along the Z direction in isolation structure 406 and one or more contact pads 446 (e.g., contact pads 152 of FIG. 1) that are close to surface 428 of isolation structure 406 and extend in the X-Y plane. Contact structures 444 can be coupled to contact pads 446 for pad-out, which can provide connections from the inside of semiconductor structure 442 (e.g., through interconnect layer 422) to an external component (e.g., on surface 428 of isolation structure 406).

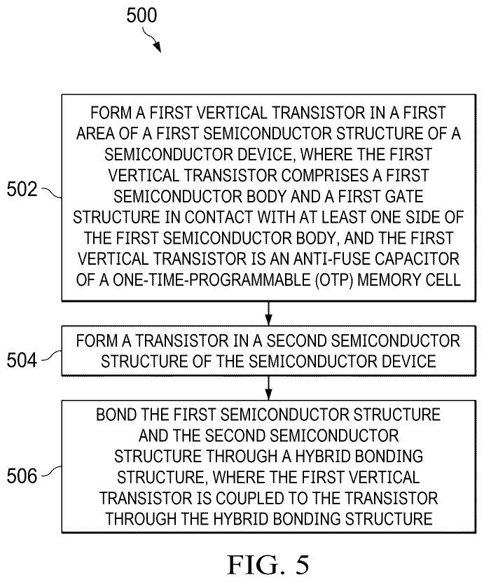

FIG. 5 illustrates a flowchart of an example method 500 for forming a semiconductor device, according to some aspects of the present disclosure. The semiconductor device can be similar to, or same as, semiconductor device 100 of FIG. 1, semiconductor device 200a of FIG. 2A, and semiconductor structure 442 of FIG. 4E, or a part of semiconductor devices 100 and 200a and semiconductor structure 442, or a structure at an intermediate fabrication process of semiconductor devices 100 and 200a and semiconductor structure 442. The method 500 can be described in view of FIGS. 4A-4E. The method 500 can include the fabrication process of forming semiconductor structures in FIGS. 4A-4E. It is understood that the operations shown in method 500 are not exhaustive and that other operations can be performed as well before, after, or between any of the illustrated operations. Further, some of the operations may be performed simultaneously, or in a different order than shown in FIG. 5.

At operation 502, a first vertical transistor (e.g., vertical transistor 116 of FIG. 1 or vertical transistor 402 of FIG. 4A) in a first area (e.g., area 122 of FIG. 1) of a first semiconductor structure (e.g., semiconductor structure 104 of FIG. 1) of the semiconductor device is formed. The first vertical transistor can include a first semiconductor body (e.g., semiconductor body 124 of FIG. 1) and a first gate structure (e.g., gate structure 126 of FIG. 1) in contact with at least one side of the first semiconductor body. The first vertical transistor can be an anti-fuse structure (e.g., an anti-fuse capacitor) of an OTP memory cell.

At operation 504, a transistor (e.g., transistor 436 of FIG. 4D) in a second semiconductor structure (e.g., semiconductor structure 102 of FIG. 1 or semiconductor structure 438 of FIG. 4D) of the semiconductor device is formed. The transistor can be an access transistor of the OTP memory cell. In some implementations, the transistor can be a planar transistor.

At operation 506, the first semiconductor structure is boned to the second semiconductor structure through a hybrid bonding structure (e.g., bonding structure 106 of FIG. 1 or bonding layers 424 and 432 of FIG. 4D). The first vertical transistor is coupled to the transistor through the hybrid bonding structure (e.g., through bonding contacts 426 and 434 of FIG. 4D).

In some implementations, a second vertical transistor (e.g., vertical transistor 112 of FIG. 1) in a second area (e.g., area 120 of FIG. 1) of the first semiconductor structure of the semiconductor device is formed. The second vertical transistor can include a second semiconductor body and a second gate structure in contact with at least one side of the second semiconductor body. A storage structure (e.g., storage structure 113 of FIG. 1) is also formed. The storage structure can be coupled to the second vertical transistor along a first direction (e.g., the Z direction). The second area can be adjacent to the first area in a second direction (e.g., the X direction) perpendicular to the first direction.

In some implementations, the first vertical transistor and the second vertical transistor are formed during a same operation. For example, the operation can include forming the first semiconductor body of the first vertical transistor in the first area of the first semiconductor structure and the second semiconductor body of the second vertical transistor in the second area of the first semiconductor structure. The first semiconductor body and the second semiconductor body can be formed on a first side of the first semiconductor structure. The operation can further include forming the first gate structure of the first vertical transistor and the second gate structure of the second vertical transistor.

In some implementations, the first area of the first semiconductor structure can be covered with a mask while forming the storage structure.

In some implementations, method 500 further includes removing a first portion of the first area of the first semiconductor structure from the first side to expose a first end (e.g., a source) of the first semiconductor body and forming a first connection line (e.g., connection line 410 of FIG. 4C) and a first contact structure (e.g., contact structure 416 of FIG. 4C). The first connection line can connect the first end of the first semiconductor body and the first contact structure, and the first contact structure can be coupled to the hybrid bonding structure (e.g., through bonding contacts 426 of FIG. 4C).

In some implementations, method 500 further includes removing a second portion of the first semiconductor structure from a second side to expose a second end (e.g., a drain) of the first semiconductor body and forming a second connection line (e.g., terminal lines 414 of FIG. 4C) in contact with the second end of the first semiconductor body. The second connection line can be floating.

In some implementations, method 500 further includes forming a third connection and a second contact structure (e.g., contact structure 418 of FIG. 4C). The third connection can connect the first gate structure and the second contact structure. The second contact structure can be coupled to the hybrid bonding structure (e.g., through bonding contacts 426 of FIG. 4C).

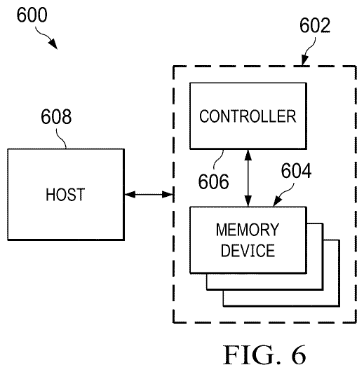

FIG. 6 illustrates a block diagram of a system 600 having one or more semiconductor devices (e.g., memory devices), according to some aspects of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more memory devices 604.

Memory device 604 can be any memory device disclosed herein, such as a memory device based on semiconductor device 100 of FIG. 1, semiconductor device 200a of FIG. 2A, or semiconductor structure 442 of FIG. 4E. In some implementations, memory device 604 can be a DRAM device. Memory controller 606 (a.k.a., a controller circuit) is coupled to memory device 604 and host device 608. Consistent with implementations of the present disclosure, memory device 604 can include a plurality of conductive interconnections through a cover layer that are in contact with conductive pads in a conductive pad layer, and memory controller 606 can be coupled to memory device 604 through at least one of the plurality of conductive interconnections. Memory controller 606 is configured to control memory device 604. For example, memory controller 606 may be configured to operate a plurality of channel structures via word lines. Memory controller 606 can manage data stored in memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program (or write) operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first array of memory cells comprising at least a first memory cell, wherein the first memory cell comprises a first vertical transistor and a storage structure coupled to the first vertical transistor in a first direction, and wherein the first array of memory cells is in a first area of a first semiconductor structure of the semiconductor device; and
a second array of memory cells comprising at least a second memory cell, wherein the second memory cell comprises a second vertical transistor in a second area of the first semiconductor structure, and wherein the second area is adjacent to the first area in a second direction perpendicular to the first direction.

2. The semiconductor device of claim 1, wherein the second memory cell is a one-time-programmable (OTP) memory cell and further comprises an access transistor coupled to the second vertical transistor, and wherein the access transistor is in a second semiconductor structure of the semiconductor device.

3. The semiconductor device of claim 1, wherein the second memory cell is a one-time-programmable (OTP) memory cell, the second vertical transistor is an access transistor of the OTP memory cell, the OTP memory cell further comprises an anti-fuse capacitor coupled to the second vertical transistor, and the anti-fuse capacitor is in a second semiconductor structure of the semiconductor device.

4. The semiconductor device of claim 2, wherein a source of the access transistor is coupled to a source of the second vertical transistor.

5. The semiconductor device of claim 2, wherein:
the second array of memory cells comprises a first group of vertical transistors coupled to a first program line through a gate of each vertical transistor of the first group of vertical transistors;
the first group of vertical transistors comprises the second vertical transistor; and
the first group of vertical transistors is comprised in a first array of vertical transistors in the second area of the first semiconductor structure.

6. The semiconductor device of claim 5, wherein:
each vertical transistor of the first group of vertical transistors is coupled to a corresponding access transistor in the second semiconductor structure through a first terminal of the vertical transistor; and
a second terminal of the vertical transistor is floating.

7. The semiconductor device of claim 5, wherein:
the second array of memory cells further comprises a second group of vertical transistors coupled to a second program line through a gate of each vertical transistor of the second group of vertical transistors; and
the second group of vertical transistors is comprised in a second array of vertical transistors in the second area of the first semiconductor structure.

8. The semiconductor device of claim 5, wherein:
the first group of vertical transistors is comprised in a same row or a same column of the first array of vertical transistors; and
a gate of each vertical transistors of the first group of vertical transistors is part of a same connection line of the first array of vertical transistors.

9. The semiconductor device of claim 8, wherein:
a terminal of each vertical transistor of the first group of vertical transistors is directly connected to a contact structure extending along the first direction; and
the contact structure is further connected to a conductive line comprising a metal, the conductive line extending in a direction perpendicular to the first direction.

10. The semiconductor device of claim 8, wherein:
a terminal of each vertical transistor of the first group of vertical transistors is directly connected to a conductive line extending along a direction perpendicular to the first direction; and
the conductive line comprises a metal.

11. A semiconductor device, comprising:
an array of one-time-programmable (OTP) memory cells comprising at least an OTP memory cell, wherein the OTP memory cell comprises a vertical transistor in a first semiconductor structure of the semiconductor device and an access transistor in a second semiconductor structure of the semiconductor device, wherein the first semiconductor structure and the second semiconductor structure are bonded through a hybrid bonding structure, and wherein the access transistor is coupled to the vertical transistor.

12. The semiconductor device of claim 11, wherein:
the semiconductor device further comprises an array of dynamic random-access memory (DRAM) cells comprising at least a DRAM cell, wherein the DRAM cell comprises a first vertical transistor and a storage structure coupled to the first vertical transistor in a first direction, and wherein the array of DRAM cells is in a first area of a first semiconductor structure of the semiconductor device;
the vertical transistor of the OTP memory cell is a second vertical transistor in a second area of the first semiconductor structure; and
the second area is adjacent to the first area in a second direction perpendicular to the first direction.

13. The semiconductor device of claim 12, wherein a source of the access transistor is coupled to a source of the second vertical transistor.

14. The semiconductor device of claim 12, wherein:
the array of OTP memory cells comprises a first group of vertical transistors coupled to a first program line through a gate of each vertical transistor of the first group of vertical transistors;
the first group of vertical transistors comprises the second vertical transistor; and
the first group of vertical transistors is comprised in a first array of vertical transistors in the second area of the first semiconductor structure.

15. The semiconductor device of claim 14, wherein:
each vertical transistor of the first group of vertical transistors is coupled to a corresponding access transistor in the second semiconductor structure through a first terminal of the vertical transistor; and
a second terminal of the vertical transistor is floating.

16. The semiconductor device of claim 14, wherein:
the array of OTP memory cells further comprises a second group of vertical transistors coupled to a second program line through a gate of each vertical transistor of the second group of vertical transistors; and
the second group of vertical transistors is comprised in a second array of vertical transistors in the second area of the first semiconductor structure.

17. The semiconductor device of claim 14, wherein:
the first group of vertical transistors is comprised in a same row or a same column of the first array of vertical transistors; and
a gate of each vertical transistors of the first group of vertical transistors is part of a same connection line of the first array of vertical transistors.

18. A method for forming a semiconductor device, comprising:
forming a first vertical transistor in a first area of a first semiconductor structure of the semiconductor device, wherein the first vertical transistor comprises a first semiconductor body and a first gate structure in contact with at least one side of the first semiconductor body, and the first vertical transistor is an anti-fuse capacitor of a one-time-programmable (OTP) memory cell;
forming a transistor in a second semiconductor structure of the semiconductor device; and
bonding the first semiconductor structure and the second semiconductor structure through a hybrid bonding structure, wherein the first vertical transistor is coupled to the transistor through the hybrid bonding structure.

19. The method of claim 18, further comprising:
forming a second vertical transistor in a second area of the first semiconductor structure, wherein the second vertical transistor comprises a second semiconductor body and a second gate structure in contact with at least one side of the second semiconductor body; and
forming a storage structure coupled to the second vertical transistor along a first direction, wherein the second area is adjacent to the first area in a second direction perpendicular to the first direction.

20. The method of claim 19, wherein the first vertical transistor and the second vertical transistor are formed during a same operation comprising:
forming the first semiconductor body of the first vertical transistor in the first area of the first semiconductor structure and the second semiconductor body of the second vertical transistor in the second area of the first semiconductor structure, wherein the first semiconductor body and the second semiconductor body are formed on a first side of the first semiconductor structure; and
forming the first gate structure of the first vertical transistor and the second gate structure of the second vertical transistor.
